(19) United States
(12) Patent Application Publication
(10) Pub. No.: US 2008/0280421 A1
(43) Pub. Date: Nov. 13, 2008

(54) WAFER DIVIDING METHOD

(75) Inventor: Masaru Nakamura, Ota-Ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/105,020

(22) Filed: Apr. 17, 2008

(30) Foreign Application Priority Data
May 11, 2007 (JP) 2007-126531

(51) Int. Cl. H01L 21/304

(52) U.S. Cl. 438/462; 257/E21.238

(57) ABSTRACT

A wafer dividing method that includes a modifying layer forming step in which a laser beam with a wavelength that can pass through the wafer is focused on the inside of the wafer from a rear surface side thereof, and applied along the street to form a modifying layer having a thickness corresponding to at least a device-finishing thickness from the front surface of the wafer; a rear surface grinding step in which an area, corresponding to the device area, of the rear surface of the wafer subjected to the modifying layer forming step is ground and formed to have a thickness corresponding to the device-finishing thickness and to have an annular reinforcing section at an area corresponding to the outer circumferential redundant area; a reinforcing section cutting step in which the wafer is cut along the inner circumference of the annular reinforcing section; a wafer support step in which the rear surface of the wafer whose annular reinforcing section is cut is stuck to a dicing tape attached to an annular frame; and a wafer rupture step in which an external force is applied to the wafer stuck to the dicing tape to rupture it along the street formed with the modifying layer.

### BACKGROUND OF THE INVENTION

1. Field of the Invention

The present invention relates to a method of dividing a wafer along a plurality of streets arranged in a lattice pattern on the front surface of the wafer, the wafer having a device area where devices are formed on a plurality of area sectioned by the streets and an outer circumferential redundant area surrounding the device area.

2. Description of the Related Art

In a semiconductor device fabrication process, the front surface of an almost-disklike semiconductor wafer is sectioned into a plurality of areas by predetermined dividing lines called streets arranged in a lattice pattern. Devices such as ICs, LSIs or the like are formed in the areas thus sectioned. The semiconductor wafer is cut along the streets to divide the areas formed with the devices therein for fabricating the individual devices. An optical device wafer in which gallium nitride-system compound semiconductor and the like are stacked on the front surface of a sapphire substrate is also cut along streets and divided into individual optical devices such as light-emitting diodes, laser diodes or the like, which are widely used in electric equipment.

In recent years, a laser processing method has been tried as a method of dividing a plate-like workpiece such as a semiconductor wafer or the like. In this laser processing method, a pulse laser beam with a wavelength that can pass through the workpiece is used and focused on the inside of a to-be-divide area for irradiation. The dividing method using such a laser processing method divides a workpiece as below. A pulse laser beam of an infrared area that can pass through a workpiece is focused on the inside of the workpiece from one side thereof for irradiation. This irradiation continuously forms modifying layers inside the workpiece to extend along predetermined dividing lines. The formation of the modifying layers lower the strength of the workpiece along the predetermined dividing lines. An external force is applied to the workpiece along the predetermined dividing lines for division. See e.g. Japanese Patent No. 3408805. The wafer divided as described above is formed to have a finishing thickness of a device by grinding or etching the rear surface of the wafer before being cut along the streets.

In recent years, it has been required to form a wafer having a thickness of 100 μm or less in order to achieve weight reduction and downsizing of electric equipment. However, if a wafer is formed to have a thickness of 100 μm or less, it will causes warps at the outer circumference thereof. Even if the wafer is held on the chuck table of a laser processing apparatus, the outer circumference of the wafer will warp. This makes it difficult to adjust the focus of a laser beam to a predetermined internal position of the wafer held on the chuck table. There arises a problem as below. A laser beam is applied along a street to the inside of a thinly formed wafer to form a modifying layer thereat. Thereafter, the wafer is picked up from the chuck table of the laser processing apparatus and is conveyed to the next step. During this conveyance, the wafer may crack along the modifying layer.

### SUMMARY OF THE INVENTION

Accordingly, it is an object of the present invention to provide a wafer dividing method that can surely form a modifying layer along a street at a predetermined internal position of a wafer and that can safely convey the wafer even formed to have a small thickness.

In accordance with an aspect of the present invention, there is provided a wafer dividing method of dividing a wafer along a plurality of streets arranged in a lattice pattern, the wafer having a device area formed with devices in a plurality of areas sectioned by the streets and an outer circumferential redundant area surrounding the device area, the method including: a modifying layer forming step in which a laser beam with a wavelength that can pass through the wafer is focused on the inside of the wafer from a rear surface side thereof, and applied along the street to form a modifying layer having a thickness corresponding to at least a device-finishing thickness from the front surface of the wafer; a rear surface grinding step in which an area, corresponding to the device area, of the rear surface of the wafer subjected to the modifying layer forming step is ground to have a thickness corresponding to the device-finishing thickness and to have an annular reinforcing section at an area corresponding to the outer circumferential redundant area; a reinforcing section cutting step in which the wafer subjected to the rear surface grounding step is cut along the inner circumference of the annular reinforcing section; a wafer support step in which the rear surface of the wafer whose annular reinforcing section is cut is stuck to a dicing tape attached to an annular frame; and a wafer rupture step in which an external force is applied to the wafer stuck to the dicing tape to rupture the wafer along the streets formed with the modifying layer.

In accordance with another aspect of the present invention, there is provided a wafer dividing method of dividing a wafer along a plurality of streets arranged in a lattice pattern, the wafer having a device area formed with devices in a plurality of areas sectioned by the streets and an outer circumferential redundant area surrounding the device area, the method including: a rear surface grinding step in which an area, corresponding to the device area, of the rear surface of the wafer is ground to have a thickness corresponding to a device-finishing thickness and to have an annular reinforcing section at an area corresponding to the outer circumferential redundant area; a modifying layer forming step in which a laser beam with a wavelength that can pass through the wafer is focused on the inside of the wafer from a rear surface side thereof, and applied along the street to form a modifying layer having a thickness corresponding to at least the device-finishing thickness from the front surface of the wafer; a reinforcing section cutting step in which the wafer subjected to the modifying layer forming step is cut along the inner circumference of the annular reinforcing section; a wafer support step in which the rear surface of the wafer whose annular reinforcing section is cut is stuck to a dicing tape attached to an annular frame; and a wafer rupture step in which an external force is applied to the wafer stuck to the dicing tape to rupture the wafer along the streets formed with the modifying layer.

According to the present invention, the wafer to be subjected to the modifying layer forming step is subjected to the modifying layer forming step before or after the execution of the rear surface grinding step where an area of the rear surface corresponding to the device area is formed to have the device-finishing thickness. In addition, the annular reinforcing section is formed at the area corresponding to the outer circumferential redundant area. Thus, the wafer will cause no warps at the outer circumference thereof. Consequently, the modifying layer forming step can surely form the modifying layer at a predetermined internal position of the wafer along the street.

According to the present invention, the wafer subjected to the rear surface grinding step is such that the area corresponding to the device area is formed to have the device-finishing thickness. However, the annular reinforcing section is formed at the area corresponding to the outer circumferential area surrounding the device area. Thus, the entire wafer maintains rigidity so that it will never crack during the conveyance to the next step.

The above and other object, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer as a wafer to be divided into individual devices by a wafer dividing method according to the present invention;

FIG. 2 is a perspective view illustrating a state where a protection member is stuck to the front surface of the semiconductor wafer in FIG. 1;

FIG. 3 is a perspective view of a laser processing apparatus used to execute a modifying layer forming step in the wafer dividing layer according to the present invention;

FIGS. 4A and 4B are explanatory views illustrating a first embodiment of the modifying layer forming step in the wafer dividing method according to the present invention;

FIG. 5 is a perspective view of a grinding device used to execute a rear surface grinding step in the wafer dividing method according to the present invention;

FIG. 6 is an explanatory view illustrating a first embodiment of the rear surface grinding step in the wafer dividing method according to the present invention;

FIG. 7 is a cross-sectional view of a semiconductor wafer that was subjected to the rear surface grinding step illustrated in FIG. 6;

FIG. 8 is a perspective view of a cutting device used to execute a reinforcing section cutting step in the wafer dividing method according to the present invention;

FIG. 9 is a view for assistance in explaining the reinforcing section cutting step in the wafer dividing method according to the present invention;

FIG. 10 is a cross-sectional view of the semiconductor wafer that was subjected to the reinforcing section cutting step illustrated in FIG. 9;

FIG. 11 is a view for assistance in explaining a wafer support step in the wafer dividing method according to the present invention;

FIG. 12 is a perspective view of a tape expansion device used to execute a wafer rupture step in the wafer dividing method according to the present invention;

FIGS. 13A and 13B are views for assistance in explaining the wafer rupture step in the wafer dividing method according to the present invention;

FIG. 14 is a view for assistance in explaining a second embodiment of the rear surface grinding step in the wafer diving method according to the present invention; and

FIG. 15 is a view for assistance in explaining a second embodiment of the modifying layer forming step in the wafer dividing method according to the present invention.

### DETAILED DESCRIPTION OF THE PREFERRED EMBODIMENTS

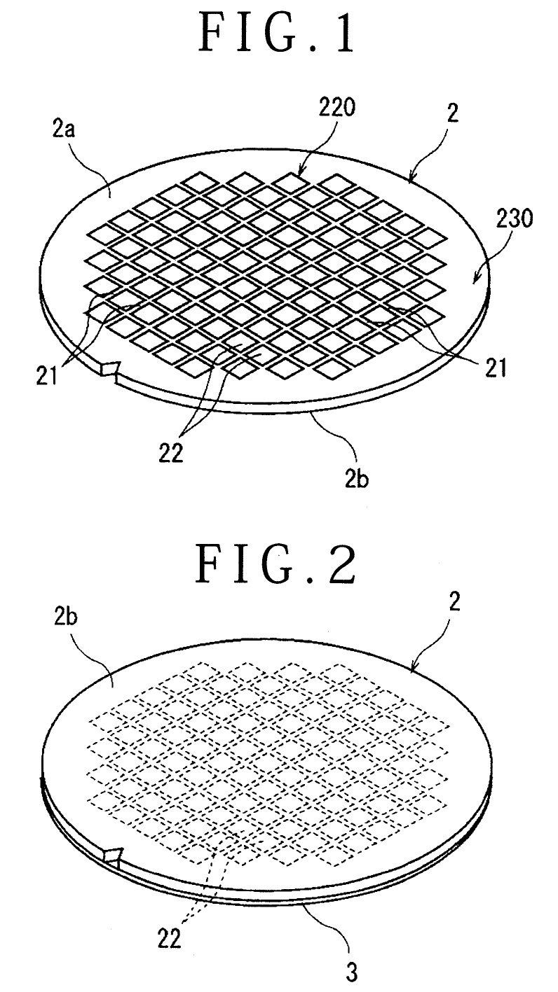

Preferred embodiments of a wafer dividing method according to the present invention will hereinafter be described in detail with reference to the accompanying drawings. FIG. 1 is a perspective view of a semiconductor wafer as a wafer to be processed by a wafer laser processing method according to the present invention. A semiconductor wafer 2 shown in FIG. 1 is made of a silicon wafer having a thickness of e.g. 350 μm. The semiconductor wafer 2 is formed on a front surface 2a with a plurality of streets 21 in a lattice pattern and devices 22 such as ICs, LSIs, etc. are formed in a plurality of areas sectioned by the streets 21. The semiconductor 2 thus configured includes a device area 220 formed with the devices 22 and an outer circumferential redundant area 230 surrounding the device area 220.

A first embodiment in which the semiconductor wafer 2 is divided along the streets 21 into the individual devices is described with reference to FIGS. 2 through 13B. When the semiconductor wafer 2 is divided along the streets 21 into the individual devices, a protection member 3 is stuck to the front surface 2a of the semiconductor wafer 2 as shown in FIG. 2 (a protection member sticking step). Thus, the rear surface 2b of the semiconductor wafer 2 is exposed.

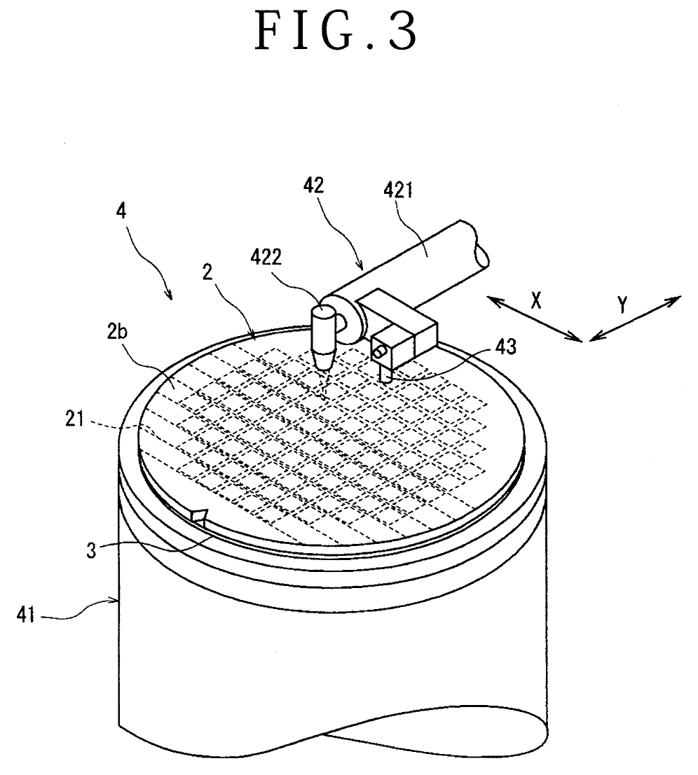

After the execution of the protection member sticking step, a modifying layer forming step is performed. In this step, a laser beam with a wavelength that can pass through the semiconductor wafer 2 is focused on the inside of the semiconductor wafer 2 from the rear surface 2b thereof and applied thereto along the street 21. This application forms a modifying layer having a thickness from the front surface 2a of the semiconductor wafer 2 corresponding to at least the finishing thickness of the device 22. This modifying layer forming layer step is executed by a laser processing apparatus shown in FIG. 3 in the illustrated embodiment. This laser processing apparatus 4 shown in FIG. 3 includes a chuck table 41 adapted to hold a workpiece; laser beam irradiation means 42 for applying a laser beam to the workpiece held on the chuck table 41; and imaging means 43 for picking up an image of the workpiece held on the chuck table 41. The chuck table 41 is configured to suck and hold the workpiece and is caused to be moved by a moving mechanism not shown in a process-transfer direction indicated with arrow X and in an indexing-transfer direction in FIG. 3.

The laser beam irradiation means 42 includes a cylindrical casing 421 arranged to extend substantially horizontally. Pulse laser beam oscillation means that includes a pulse laser beam oscillator composed of a YAG laser oscillator or YVO4 laser oscillator not shown and cyclic frequency setting means is arranged in the casing 421. A concentrator 422 is attached to the leading end of the casing 421 to collect the laser beam emitted from the pulse laser beam oscillation means.

The imaging means 43 attached to the leading end of the casing 421 constituting part of the laser beam irradiation means 42 is configured to include infrared illumination means; an optical system; and an image pickup device (infrared CCD); as well as a usual image pickup device (CCD) which picks up an image through a visible ray in the illustrated embodiment. The infrared illumination means emits an infrared ray to a workpiece. The optical system captures the infrared ray emitted from the infrared illumination means. The image pickup device outputs an electric signal corresponding to the infrared ray captured by the optical system. The usual image pickup device picks up an image through a visible ray. The imaging means 43 sends a signal of the picked-up image to control means not shown.

To execute the modifying layer forming step using the laser processing apparatus 4 described above, the semiconductor wafer 2 is put on the chuck table 41 of the laser processing apparatus 4 with the protection member 3 facing downward as shown in FIG. 3. The semiconductor wafer 2 is sucked and held on the chuck table 41 by suction means not shown (a wafer holding step). Thus, the semiconductor wafer 2 sucked and held on the chuck table 41 is such that the rear surface 2b faces upward.

After the execution of the wafer holding step described above, a modifying layer forming step is performed. In this step, a laser beam with a wavelength that can pass through a silicon wafer forming the semiconductor wafer 2 is applied to the semiconductor wafer 2 along the street 21 from the rear surface 2b thereof to form a modifying layer inside the semiconductor wafer 2 to extend along the street 21. To execute the modifying layer forming step, the chuck table 41 which has sucked and held the semiconductor wafer 2 is first located at a position immediately below the imaging means 43 by a moving mechanism not shown. Alignment operation is executed to detect a process area of the semiconductor wafer 2 to be laser-processed by the imaging means 43 and by the control means not shown.

More specifically, the imaging means 43 and the control means not shown execute image processing such as pattern matching for performing position adjustment between the street 21 formed to extend in a predetermined direction of the semiconductor wafer 2 and the concentrator 422 of the laser beam irradiation means 42 for emitting a laser beam along the street 21. Thus, alignment of a laser beam irradiation position is executed. Similarly, the alignment of the laser beam irradiation position is performed on the street 21, in the semiconductor wafer 2, extending in a direction perpendicular to the above-mentioned predetermined direction (an alignment step). In this case, the front surface 2a of the semiconductor wafer 2 formed with the streets 21 is located on the downside. However, the imaging means 43 includes the infrared illumination means, the optical system which captures an infrared ray and the image pickup device (infrared CCD) which outputs an electric signal corresponding to the infrared ray. Thus, the streets 21 can be imaged through the semiconductor wafer from the rear surface 2b.

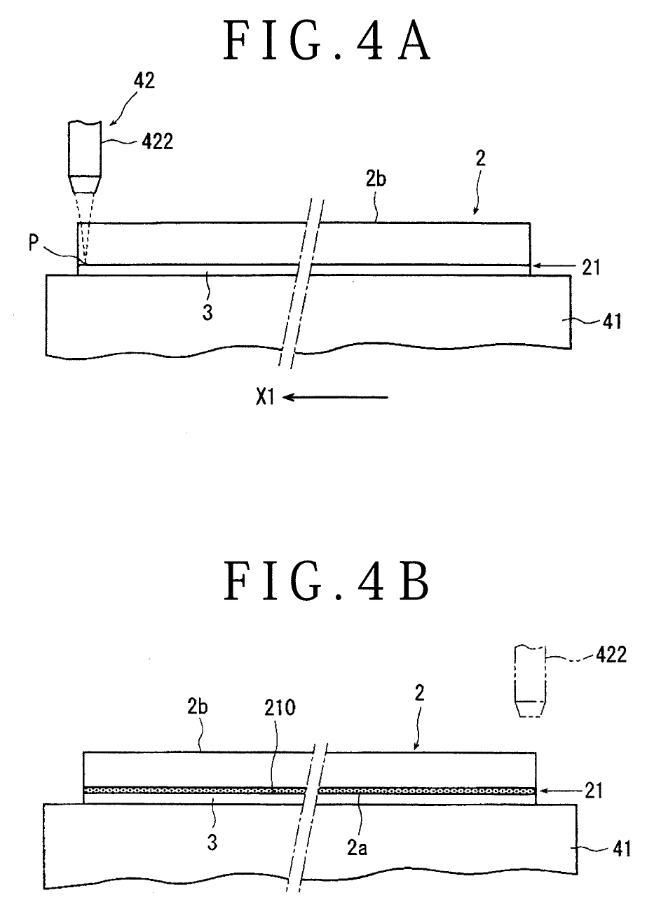

After the execution of the alignment step described above, as shown in FIG. 4A, the chuck table 41 is moved to a laser beam irradiation area at which the concentrator 422 of the laser beam irradiation means 42 for emitting a laser beam is located and one end (the left end in FIG. 4A) of a predetermined street 21 is located at a position immediately below the concentrator 422 of the laser beam irradiation means 42. The chuck table 41 is moved at a predetermined transfer speed in the direction indicated with arrow X1 in FIG. 4A while a pulse laser beam that can pass through the silicon wafer is emitted from the concentrator 422. When the irradiation position of the concentrator 422 reaches the other end position of the street 21 as shown in FIG. 4B, the irradiation of the pulse laser beam is stopped and the movement of the chuck table 41 is stopped. In the modifying layer forming step, by adjusting the focal point P of the pulse laser beam to the vicinity of the front surface 2a (the under surface) of the semiconductor wafer 2, the semiconductor wafer 2 is formed with a modifying layer 210 exposed to the front surface 2a (the under surface) and extending from the front surface 2a toward the inside. This modifying layer 210 is formed as a melting re-solidification layer.

The processing conditions for the modifying layer forming step described above are set, for example, as follows:

| | |
|---|---|
| Light source | LD excited Q switch Nd: YVO4 |
| | laser |
| Wavelength | pulse laser having a wavelength |
| | of 1064 nm |
| Cyclic frequency | 100 kHz |
| Pulse output | 10 μJ |
| Focusing spot diameter | φ 1 μm |
| Process-transfer rate | 100 mm/second |

Under the processing conditions mentioned above, the modifying layer formed once has a thickness of about 50 μm. If the finishing thickness of a device is 50 μm or less, it is only need to form one modifying layer. In this way, the modifying layer forming step is executed on the semiconductor wafer 2 along all the streets 21 extending in the predetermined directions thereof. Thereafter, the chuck table 41 is turned at 90 degrees and the modifying layer forming step is executed along each of the streets 21 extending perpendicularly to the predetermined direction mentioned above.

The modifying layer forming step described above is executed before the execution of a rear surface grinding step described later in which the rear surface of the semiconductor wafer 2 is ground to form the device 22 with a finishing thickness. Since the semiconductor wafer 2 has a thickness of as thick as e.g. 350 μm, it will not cause warps at the outer circumference thereof. Thus, in the modifying layer forming step, the modifying layer 210 can surely be formed at the predetermined internal position of the semiconductor wafer 2 along each of the streets 21.

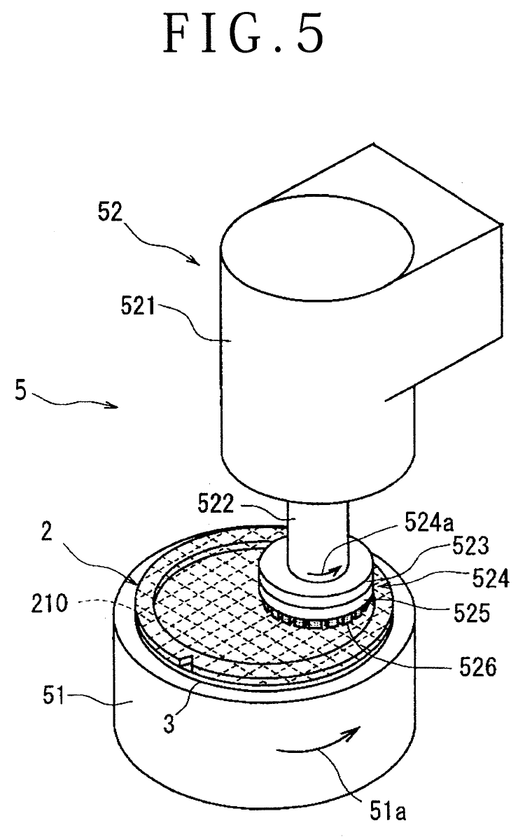

After the execution of the modifying layer forming step described above, a rear surface grinding step is executed. In this step, an area of the rear surface of the semiconductor wafer 2 corresponding to the device area 220 is ground and formed to have a thickness corresponding to the finishing thickness of the device 22. In addition, an annular reinforcing section is formed at an area corresponding to the outer circumferential redundant area 230. The rear surface grinding step is executed by a grinding device shown in FIG. 5 in the illustrated embodiment. The grinding device shown in FIG. 5 includes a chuck table 51 adapted to hold a wafer as a workpiece and grinding means 52 for grinding a to-be-processed surface of the wafer held on the chuck table 51. The chuck table 51 sucks and holds the wafer on the upper surface thereof and is rotated in the direction indicated with arrow 51a in FIG. 5. The grinding means 52 includes a spindle housing 521; a rotational spindle 522 rotatably supported by the spindle housing 521 and rotated by a rotational drive mechanism not shown; a mounter 523 attached to the lower end of the rotational spindle 522; and a grinding wheel 524 attached to the lower surface of the mounter 523. The grinding wheel 524 includes a disklike base 525 and a grinding stone 526 annularly attached to the lower surface of the base 525. The base 525 is attached to the lower surface of the mounter 523.

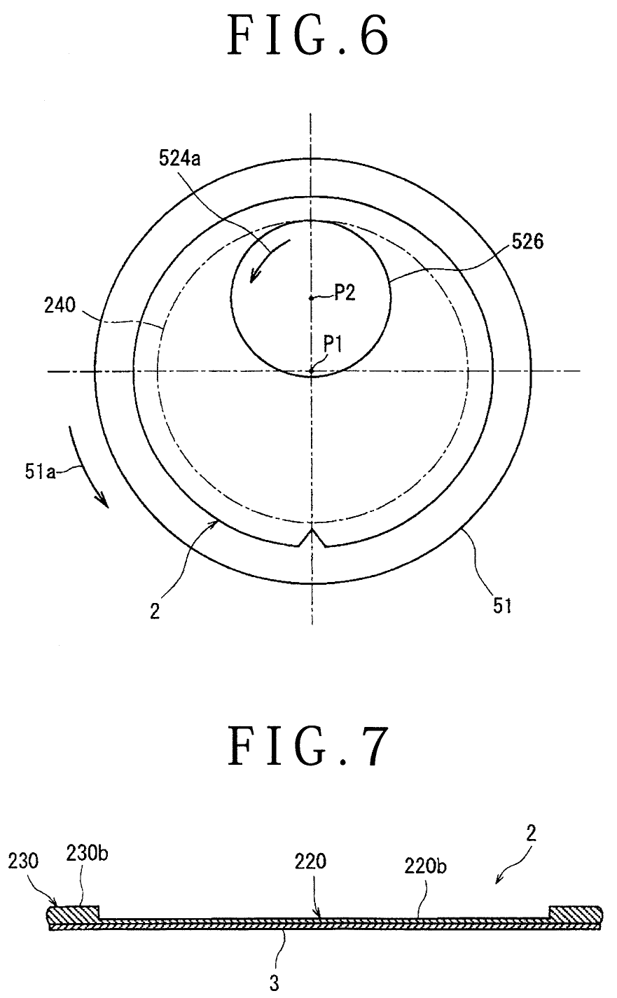

The rear surface grinding step is executed as below using the grinding device 5 described above. The semiconductor wafer 2 subjected to the modifying layer forming step described above is put on the upper surface (the holding surface) of the chuck table 51 with the protection member 3 facing downward and is sucked and held on the chuck table 51. Thus, the semiconductor wafer 2 sucked and held on the chuck table 51 is such that the rear surface 2b faces upward. A description is here given of the relationship between the semiconductor wafer 2 held on the chuck table 51 and the annular grinding stone 526 constituting part of the grinding wheel 524 with reference to FIG. 6. The rotational center P1 of the chuck table 51 is eccentric to the rotational center P2 of the annular grinding stone 526. The outer diameter of the annular grind stone 526 is set to a size smaller than the diameter of a boarder line 240 between the device area 220 and outer circumferential redundant area 230 of the semiconductor wafer 2 and greater than the radius of the boarder line 240. Consequently, the annular grinding stone 526 passes the rotational center P1 (the center of the semiconductor wafer 2) of the chuck table 51.

As shown in FIGS. 5 and 6, the grinding wheel 524 is rotated in the direction indicated with arrow 524a at 6000 rpm while the chuck table 51 is rotated in the direction indicated with arrow 51a at 300 rpm and the grinding wheel 524 is moved downward so that the grinding stone 526 is brought into contact with the rear surface of the semiconductor wafer 2. Then, the grinding wheel 524 is grinding-transferred downward to a predetermined level at a predetermined grinding-transfer rate. As a result, in the rear surface of the semiconductor wafer 2 an area corresponding to the device area 220 is ground and removed to form a circular recess portion 220b with a device-finishing thickness (e.g. 50 μm). In addition, an area corresponding to the outer circumferential redundant area 230 is left to a thickness of 350 μm to form an annular reinforcing section 230b in the illustrated embodiment (the rear surface grinding step). Incidentally, the modifying layers 210 formed along the streets 21 are exposed to the area of the rear surface corresponding to the device area 220 ground to have a device-finishing thickness (e.g. 50 μm).

The semiconductor wafer 2 subjected to the rear surface grinding step as described above is formed so that the area corresponding to the device area 220 has a device-finishing thickness (e.g. 50 μm). However, the annular reinforcing section 230b is formed at the area corresponding to the outer circumferential redundant area 230 surrounding the device area 220. Thus, since the entire wafer can maintain rigidity, it will not crack during the conveyance to the next step. If the entire rear surface of the semiconductor wafer 2 is ground and thinned in the rear surface grinding step, the semiconductor wafer 2 formed with modifying layers causes cracks at the outer circumference thereof to be damaged. However, since the annular reinforcing section 230b is left and formed at the outer circumferential portion in the rear surface grinding step of the embodiment, the semiconductor wafer 2 will not be damaged at the outer circumference thereof.

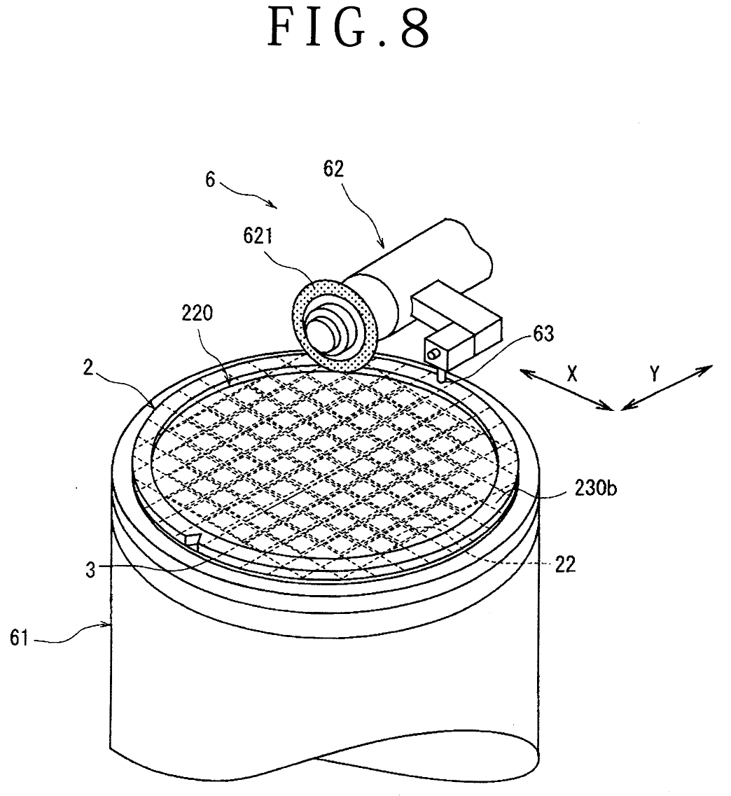

After the execution of the rear surface grinding step, a reinforcing section cutting step is executed in which the semiconductor wafer 2 formed with the annular reinforcing section 230b is cut along the inner circumference of the reinforcing section 230b. This reinforcing section cutting step is executed using a cutting device 6 shown in FIG. 8 in the illustrated embodiment. The cutting device 6 shown in FIG. 8 includes a chuck table 61 provided with suction-holding means; cutting means 62 provided with a cutting blade 621; and imaging means 63 for picking up a workpiece held on the chuck table 61. The chuck table 61 is designed to be moved in the direction indicated with arrow X in FIG. 8 by a moving mechanism not shown. In addition, the chuck table 61 is designed to be rotated by a rotating mechanism not shown. The cutting blade 621 of the cutting means 62 is composed of a resin bond grinding stone blade or a metal bond grinding stone blade. The resin bond grinding stone blade is composed of diamond abrasive grains joined together with a resin bond. The metal bond grinding stone blade is composed of diamond abrasive grains joined together with a metal bond. The imaging means 63 sends a picture signal resulting from a picked-up image of a cutting area to control means not shown.

The reinforcing section cutting step executed using the cutting device 6 mentioned above is described with reference to FIGS. 8 to 10. Referring to FIG. 8, the semiconductor wafer 2 subjected to the rear surface grinding step described above to form the annular reinforcing section 230b is put on the chuck table 61 of the cutting device 6 with the protection member 3 facing downward. Suction means not shown is actuated to hold the semiconductor wafer 2 on the chuck table 6 via the protection member 3. Thus, the semiconductor wafer 2 causes the rear surface 2b formed with the annular reinforcing section 230b to face upward. In this way, the chuck table 61 adapted to suck and hold the semiconductor wafer 2 via the protection member 3 is located at a position immediately below the imaging means 63 by a moving mechanism not shown.

After the chuck table 61 is located at a position immediately below the imaging means 63, an alignment step is executed in which the imaging means and control means not shown detect a to-be-cut area of the semiconductor wafer 2. More specifically, the imaging means 63 and control means not shown execute alignment work in which the cutting blade 621 is aligned with a border section between the device area 220 and outer circumferential redundant area 230 of the semiconductor wafer 2, i.e., with the inner circumferential surface of the annular reinforcing section 230b.

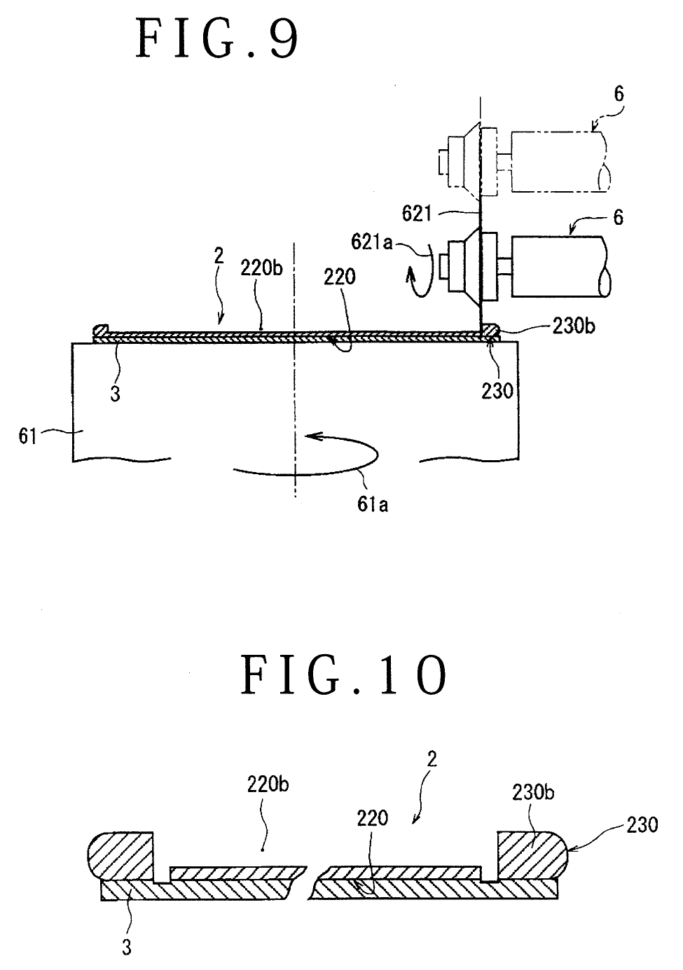

After the alignment is executed thus above to detect the to-be-cut area of the semiconductor 2 held on the chuck table 61, the chuck table 61 holding the semiconductor wafer 2 is moved to the to-be-cut area. Then, the cutting blade 621 of the cutting means 62 is located at a position immediately below the inner circumferential surface of the reinforcing section 230b formed on the semiconductor wafer 2 held by the chuck table 61. As shown in FIG. 9, the cutting blade 621 is rotated in the direction indicated with arrow 621a to be incision-transferred downward from the standby position indicated with a two-dot chain line and is located at a predetermined incision-transfer position as indicated with a solid line. This incision-transfer position is set, for example, at a position slightly below the front surface 2a (the lower surface) of the semiconductor wafer 2, namely, at a position where the cutting blade 621 reaches the protection member 3.

Next, while the cutting blade 621 is rotated in the direction indicated with arrow 621a as described above, the chuck table 61 is caused to turn in the direction indicated with arrow 61a in FIG. 9. The chuck table 61 is turned once to cut the semiconductor wafer 2 along the inner circumference of the annular reinforcing section 230b as shown in FIG. 10.

Incidentally, although the reinforcing section cutting step described above is executed using the cutting device by way of example, it may be executed using a laser processing apparatus. That is to say, a pulse laser beam with a wavelength (e.g. 355 nm) that can pass through the wafer is applied to the inner circumference of the annular reinforcing section 230b of the semiconductor wafer 2 for abrasion processing. Thus, the annular reinforcing section 230b formed on the semiconductor wafer 2 is cut along the inner circumference thereof.

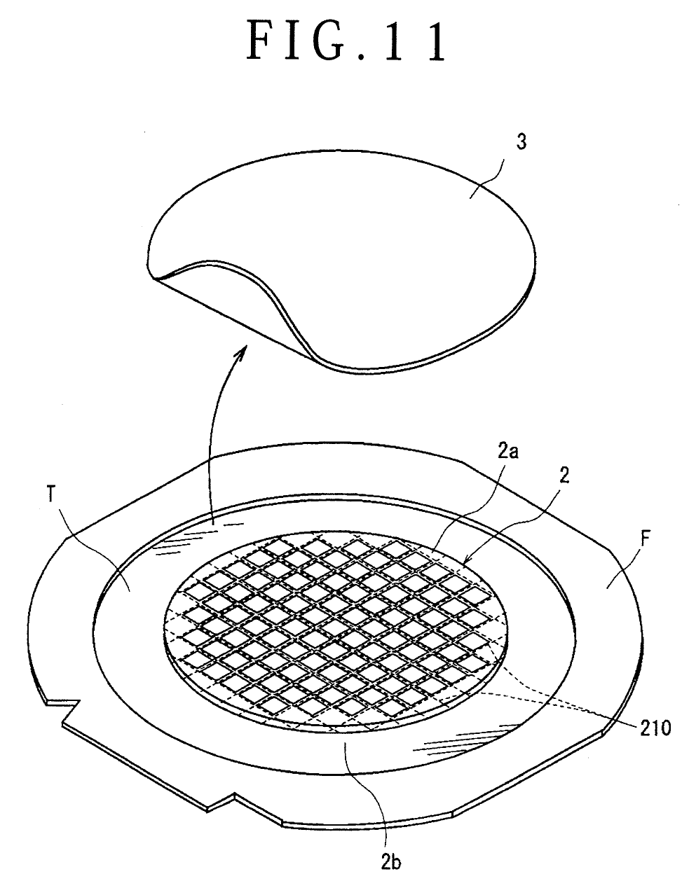

After the execution of the reinforcing section cutting step described above, a wafer support step is executed in which the semiconductor wafer 2 whose annular reinforcing section 230b is cut off is stuck at the rear surface 2b to a dicing tape attached to an annular frame. Referring to FIG. 11, the semiconductor wafer 2 subjected to the reinforcing section cutting step is stuck at the rear surface 2b to the front surface of the dicing tape T attached to the annular frame F. Then, the protection member 3 stuck to the front surface 2a of the semiconductor wafer 2 is peeled (a protection member peeling step).

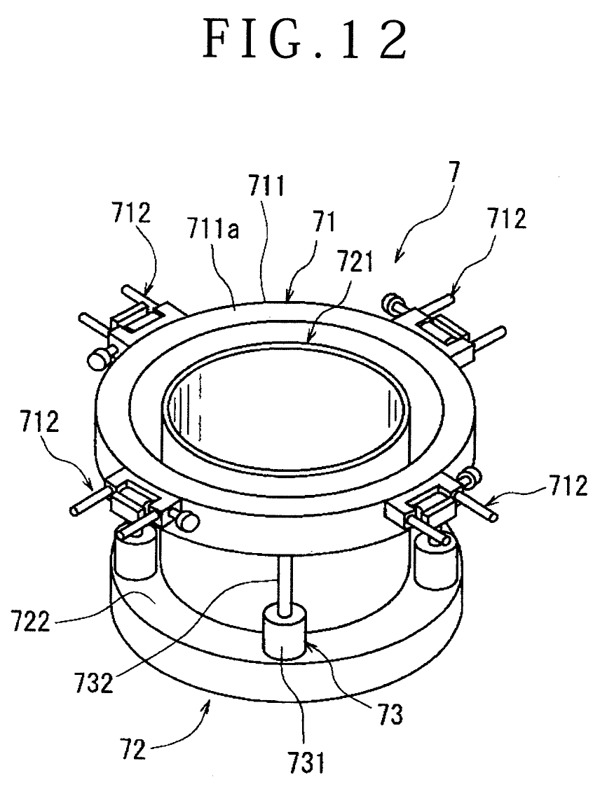

A wafer rupture step is next executed in which an external force is applied to the semiconductor wafer 2 stuck to the dicing tape T to rupture it along the streets 21 formed with the modifying layers 210. This wafer rupture step is executed using a tape expansion device 7 shown in FIG. 12. The tape expansion device 7 shown in FIG. 12 includes frame holding means 71 for holding the annular frame F and tape expansion means 72 for expanding the dicing tape T attached to the frame F held by the frame holding means 71. The frame holding means 71 includes an annular frame holding member 711 and a plurality of clamps 712 as securing means arranged on the outer circumference of the frame holding member 711. The upper surface of the frame holding member 711 is formed as a placing surface 711a adapted to place the annular frame F thereon. The annular frame F is placed on the placing surface 711a. The frame F placed on the placing surface 711a is secured to the frame holding member 711 with the clamps 712. The frame holding means 71 thus configured is supported by the tape expansion means 72 so as to be movable upward and downward.

The tape expansion means 72 includes an expansion drum 721 disposed inside the annular frame holding member 711. This expansion drum 721 has internal and external diameters smaller than the inner diameter of the annular frame F and greater than the external diameter of the semiconductor wafer 2 stuck to the dicing tape T attached to the annular frame F. The expansion drum 721 is provided with a support flange 722 at the lower end. The tape expansion means 72 in the illustrated embodiment includes support means 73 which can move the annular frame holding member 711 upward and downward.

The support means 73 is composed of a plurality of air cylinders 731 arranged on the support flange 722. The air cylinders 731 have piston rods 732 connected to the lower surface of the annular frame support member 711. The support means 73 composed of the air cylinders 731 as mentioned above cause the frame holding means 711 to move upward and downward between a reference position wherein the placing surface 711a is almost equal in height to the upper end of the expansion drum 721 and an expansion position below by a predetermined amount from the upper end of the expansion drum 721. Thus, the support means 73 composed of the air cylinders 731 functions as expansion-movement means for relatively moving the expansion drum 721 and the frame holding means 711 upward and downward.

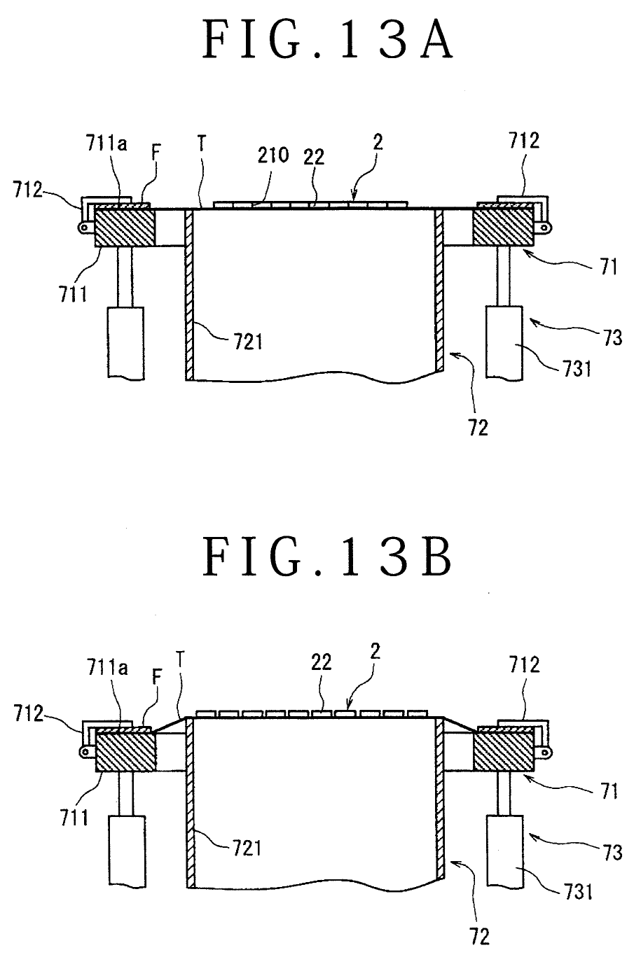

A description is given of a wafer rupture step executed using the tape expansion device 7 configured as described above with reference to FIGS. 13A and 13B. The dicing tape T to which the rear surface 2b of the semiconductor wafer 2 (formed with the modifying layers 210 along the streets 21) is stuck is attached to the annular frame F. This annular frame F is placed on the placing surface 711a of the frame holding member 711 constituting part of the frame holding means 71 and is secured to the frame holding member 711 with the cramps 712 as shown in FIG. 13A. At this time, the frame holding member 711 is located at the reference position shown in FIG. 13A. The plurality of air cylinders 731 as the support means 73 constituting the tape expansion means 72 is actuated to lower the annular frame holding member 711 to the expansion position shown in FIG. 13B. Also the annular frame F secured onto the placing member 711a of the frame holding member 711 is lowered, whereby the dicing tape T attached to the annular frame F is expanded while being in contact with the upper end edge of the expansion drum 721. Consequently, a tensile force acts radially on the semiconductor wafer 2 stuck to the dicing tape T to thereby rupture it along the streets 21 that are lowered in strength due to the formation of the modifying layers 210. Thus, the semiconductor wafer 2 is divided into individual devices 22.

A description is next given of a wafer dividing method according to a second embodiment of the present invention. The execution order of the modifying layer forming step and the rear surface grinding step in the first embodiment is reversed in the second embodiment. In the second embodiment, after the protection member sticking step is executed in which the protection member 3 is stuck to the front surface 2a of the semiconductor wafer 2 as shown in FIG. 2, the rear surface grinding step is executed. In this step, an area of the rear surface of the semiconductor wafer 2 corresponding to the device area 220 is ground and formed to have a thickness corresponding to the finishing thickness of the device 22. In addition, an annular reinforcing section is formed at an area corresponding to the outer circumferential redundant area 230. The rear surface grinding step is executed by the grinding device 5 shown in FIG. 5.

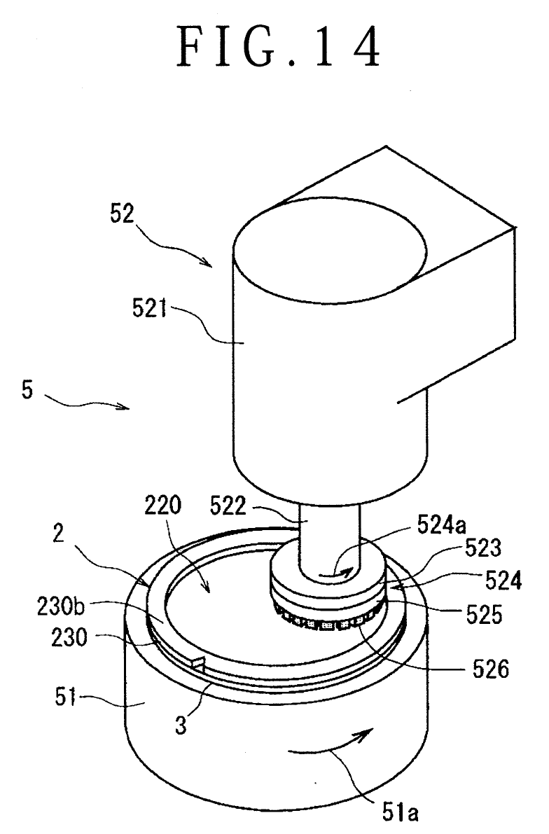

Specifically, the rear surface grinding step described above is executed while the semiconductor wafer 2 is held on the chuck table 51 of the grinding device 5 with the rear surface 2b facing upward as shown in FIG. 14. As a result, an area of the rear surface of the semiconductor wafer 2 corresponding to the device area 220 is ground and formed to have a thickness corresponding to the finishing thickness of the device 22. In addition, an annular reinforcing section 230b is formed at an area corresponding to the outer circumferential redundant area 230. The semiconductor wafer 2 subjected to the rear surface grinding step as described above is formed so that the area corresponding to the device area 220 has a device-finishing thickness (e.g. 50 μm). However, the annular reinforcing section 230b is formed at the area corresponding to the outer circumferential redundant area 230 surrounding the device area 220. Thus, since the entire wafer can maintain rigidity, it will not crack during the conveyance to the next step.

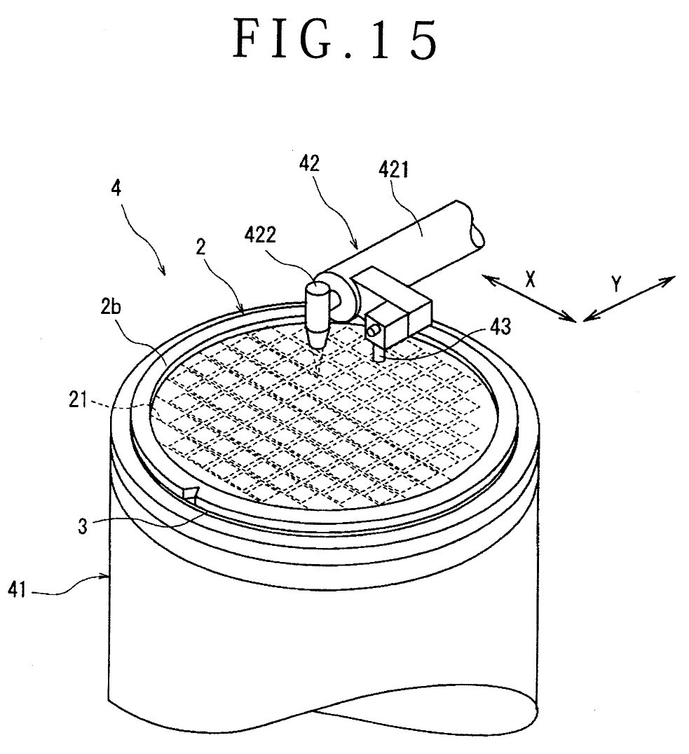

After the execution of the rear surface grinding step described above, the modifying layer forming step is performed. In this step, a laser beam with a wavelength that can pass through the semiconductor wafer 2 is focused on the inside of the semiconductor wafer 2 formed with the annular reinforcing section 230b from the rear surface 2b thereof and applied thereto along the street 21. This application forms a modifying layer having a thickness from the front surface 2a of the semiconductor wafer 2 corresponding to at least the device-finishing thickness. This modifying layer forming layer step is performed by the laser processing apparatus shown in FIG. 3. Specifically, the modifying layer forming step described above is executed while the semiconductor wafer 2 subjected to the rear surface grinding step described above is held on the chuck table 41 of the laser processing apparatus 4 with the rear surface 2b facing upward as shown in FIG. 15.

In this case, it is enough that a laser beam irradiation range is the device area 220 of the semiconductor wafer 2, that is, a laser beam is not applied to the outer circumferential redundant area 230 formed with the annular reinforcing section 230b. As described above, the modifying layer forming step in the second embodiment is executed after the portion of the rear surface of the semiconductor wafer 2 corresponding to the device area 220 is ground and formed to have the finishing thickness (e.g. 50 μm) of the device 22. However, the annular reinforcing section 230b is formed at the area of the semiconductor wafer 2 corresponding to the outer circumferential redundant area surrounding the device area 220. Thus, the semiconductor wafer 2 causes no warps at the outer circumference thereof. Consequently, the modifying layer forming step can surely form the modifying layers 210 at respective predetermined internal positions of the semiconductor wafer 2 so as to extend along the respective streets 21.

After the rear surface grinding step and modifying layer forming step are executed as described above, the reinforcing section cutting step, the wafer support step and the wafer rupture step are executed as with the first embodiment.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer dividing method of dividing a wafer along a plurality of streets arranged in a lattice pattern, the wafer having a device area formed with devices in a plurality of areas sectioned by the streets and an outer circumferential redundant area surrounding the device area, the method comprising:
a modifying layer forming step in which a laser beam with a wavelength that can pass through the wafer is focused on the inside of the wafer from a rear surface side thereof, and applied along the street to form a modifying layer having a thickness corresponding to at least a device-finishing thickness from the front surface of the wafer;
a rear surface grinding step in which an area, corresponding to the device area, of the rear surface of the wafer subjected to the modifying layer forming step is ground to have a thickness corresponding to the device-finishing thickness and to have an annular reinforcing section at an area corresponding to the outer circumferential redundant area;
a reinforcing section cutting step in which the wafer subjected to the rear surface grounding step is cut along the inner circumference of the annular reinforcing section;
a wafer support step in which the rear surface of the wafer whose annular reinforcing section is cut is stuck to a dicing tape attached to an annular frame; and
a wafer rupture step in which an external force is applied to the wafer stuck to the dicing tape to rupture the wafer along the streets formed with the modifying layer.

2. A wafer dividing method of dividing a wafer along a plurality of streets arranged in a lattice pattern, the wafer having a device area formed with devices in a plurality of areas sectioned by the streets and an outer circumferential redundant area surrounding the device area, the method comprising:
a rear surface grinding step in which an area, corresponding to the device area, of the rear surface of the wafer is ground to have a thickness corresponding to a device-finishing thickness and to have an annular reinforcing section at an area corresponding to the outer circumferential redundant area;
a modifying layer forming step in which a laser beam with a wavelength that can pass through the wafer is focused on the inside of the wafer from a rear surface side thereof, and applied along the street to form a modifying layer having a thickness corresponding to at least the device-finishing thickness from the front surface of the wafer;
a reinforcing section cutting step in which the wafer subjected to the modifying layer forming step is cut along the inner circumference of the annular reinforcing section;
a wafer support step in which the rear surface of the wafer whose annular reinforcing section is cut is stuck to a dicing tape attached to an annular frame; and
a wafer rupture step in which an external force is applied to the wafer stuck to the dicing tape to rupture the wafer along the streets formed with the modifying layer.
